(19) United States
(12) Patent Application Publication
(10) Pub. No.: US 2013/0171807 A1
(43) Pub. Date: Jul. 4, 2013

(54) METHODS OF FABRICATING A SEMICONDUCTOR DEVICE INCLUDING DUAL TRANSISTORS

(71) Applicant: Samsung Electronics Co., Ltd., Suwon-Si (KR)

(72) Inventors: Jongryeol YOO, Osan-si (KR); Seong Hoon JEONG, Seongnam-si (KR); Bonghyun KIM, Incheon (KR); Hyojung KIM, Gwacheon-si (KR); Dongwoon SHIN, Seongnam-si (KR); Soojin HONG, Guri-si (KR)

(73) Assignee: Samsung Electronics Co., Ltd., Suwon-Si (KR)

(21) Appl. No.: 13/678,002

(22) Filed: Nov. 15, 2012

(30) Foreign Application Priority Data
Dec. 29, 2011 (KR) 10-2011-0145800

(51) Int. Cl. H01L 21/02

(52) U.S. Cl. CPC H01L 21/02381
USPC 438/479; 438/488

(57) ABSTRACT

Provided are a semiconductor device having dual transistors, and methods of fabricating a semiconductor device, including sequentially forming an insulating layer and a polysilicon layer on a substrate having a first region and a second region, forming a first mask to cover the polysilicon layer on the second region, injecting at least one n-type impurity into the polysilicon layer on the first region to form an N-region, injecting nitrogen into the N-region, forming a second mask to cover the N-region, and injecting at least one p-type impurity into the polysilicon layer on the second region to form a P-region.

### CROSS-REFERENCE TO RELATED APPLICATIONS

This U.S. non-provisional patent application claims the benefit of priority under 35 U.S.C. §119 from Korean Patent Application No. 10-2011-0145800, filed on Dec. 29, 2011, in the Korean Intellectual Property Office, the entire contents of which are hereby incorporated by reference.

### BACKGROUND OF THE INVENTION

1. Field

Example embodiments relate to a dual transistor semiconductor device. Other example embodiments relate to methods of fabricating a semiconductor device including dual transistors.

2. Background

CMOS is the acronym for Complementary Metal-Oxide Semiconductor, in which N-type and P-type MOS field effect transistors (MOSFETs) are complementarily connected with each other for constructing integrated circuits.

Two important characteristics of CMOS devices are high noise immunity and low static power consumption. Significant power is only drawn when the transistors in the CMOS device are switching between on and off states. That is, the CMOS devices use almost no power in the static state. Consequently, CMOS devices do not produce as much waste heat as other forms of logic (e.g., transistor-transistor logic or NMOS logic). CMOS also allows a high density of logic functions on a chip. It was primarily for this reason that CMOS became the most used technology to be implemented in very large-scale integration (VLSI) chips, a large-capacity memory chip, a mobile device, a camera, an electronic calculator, an electronic notebook, or a micro-processor.

### SUMMARY

Example embodiments relate to a dual transistor semiconductor device. Other example embodiments relate to methods of fabricating a semiconductor device including dual transistors.

Example embodiments provide a method of fabricating a CMOS device with improved electric reliability.

According to example embodiments, a method of fabricating a semiconductor device includes sequentially forming an insulating layer and a polysilicon layer on a substrate having a first region and a second region, forming a first mask to cover the polysilicon layer on the second region, injecting at least one n-type impurity into the polysilicon layer on the first region to form an N-region, injecting nitrogen into the N-region, forming a second mask to cover the N-region, and injecting at least one p-type impurity into the polysilicon layer on the second region to form a P-region.

In example embodiments, the sequentially forming of the insulating layer and the polysilicon layer may include forming an undoped polysilicon.

In example embodiments, the sequentially forming of the insulating layer and the polysilicon layer may include forming a polysilicon doped with at least one selected from n-type elements, p-type elements, carbon, oxygen, and nitrogen.

In example embodiments, the sequentially forming of the insulating layer and the polysilicon layer may include forming a lower polysilicon layer on the insulating layer, and forming an upper polysilicon layer on the lower polysilicon layer. Each of the lower and upper polysilicon layers may include a doped or undoped polysilicon layer.

In example embodiments, the injecting of the nitrogen into the N-region may be performed using at least one selected from an ion implantation, a plasma doping process, and a thermal nitridation.

In example embodiments, the injecting of the nitrogen into the N-region includes injecting the nitrogen at a dose of about 1×10¹⁵ to 1×10¹⁶ atom/cm².

In example embodiments, the method may further include performing a thermal treatment on the polysilicon layer including the N- and P-regions.

In example embodiments, the method may further include forming a metal layer on the polysilicon layer including the N- and P-regions, and etching the metal layer and the polysilicon layer to form NMOS and PMOS electrodes on the first and second regions, respectively.

According to example embodiments, a method of fabricating a semiconductor device includes providing a polysilicon layer over a substrate having at least two active regions, providing a first mask over a first active region of the at least two active regions and exposing a second active region of the at least two active regions, forming a first polysilicon region from the exposed second active region, introducing nitrogen into the first polysilicon region, providing a second mask over the first polysilicon region with the nitrogen, wherein the first active region is exposed by the second mask, and forming a second polysilicon region from the exposed first active region. The first polysilicon region has a conductivity type the same as a conductivity type of the first active region, and the second polysilicon region has a conductivity type the same as a conductivity type of the second active region.

In example embodiments, the providing of the polysilicon layer may include forming an upper polysilicon layer over a lower polysilicon layer. One selected from the upper polysilicon layer and the lower polysilicon layer may be doped.

In example embodiments, the introducing of the nitrogen may be performed until nitrogen within the first polysilicon region forms a poly grain boundary.

According to example embodiments, there is provided a semiconductor device including a substrate having a first region and a second region, an insulating layer over the first and the second regions, and a polysilicon layer including a N-region containing at least one n-type impurity and a P-region containing at least one p-type impurity. The N-region is over the first region and the P-region is over the second region, and nitrogen atoms are in the N-region containing the at least one n-type impurity.

In example embodiments, the polysilicon layer may include an undoped polysilicon.

In example embodiments, the polysilicon layer may include a polysilicon doped with at least one selected from n-type elements, p-type elements, carbon, oxygen, and nitrogen.

In example embodiments, the nitrogen atoms may be injected into the N-region at a dose of about 1×10¹⁵ to 1×10¹⁶ atom/cm².

In example embodiments, the second active region may be within the first active region, and the first active region and the second active region may be either adjoined to each other or separated from each other.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIGS. 1A, 1B, 2 through 9 are sectional views illustrating a method of fabricating a semiconductor device according to example embodiments.

FIG. 10 is a graph showing a distribution of a nitrogen concentration in NMOS electrode, after performing processes described with reference to FIGS. 4 through 7.

FIG. 11 is a graph showing a relation between a concentration of n-type impurities in an NMOS transistor and a nitrogen doping concentration.

FIG. 12 is a graph showing sheet resistances measured from three transistors A, B and C of FIG. 11.

FIG. 13A is a block diagram illustrating a memory card including a semiconductor device according to example embodiments.

FIG. 13B is a block diagram illustrating an information processing system including a semiconductor device according to example embodiments.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Various example embodiments will now be described more fully with reference to the accompanying drawings in which some example embodiments are shown. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments relate to a dual transistor semiconductor device. Other example embodiments relate to methods of fabricating a semiconductor device including dual transistors.

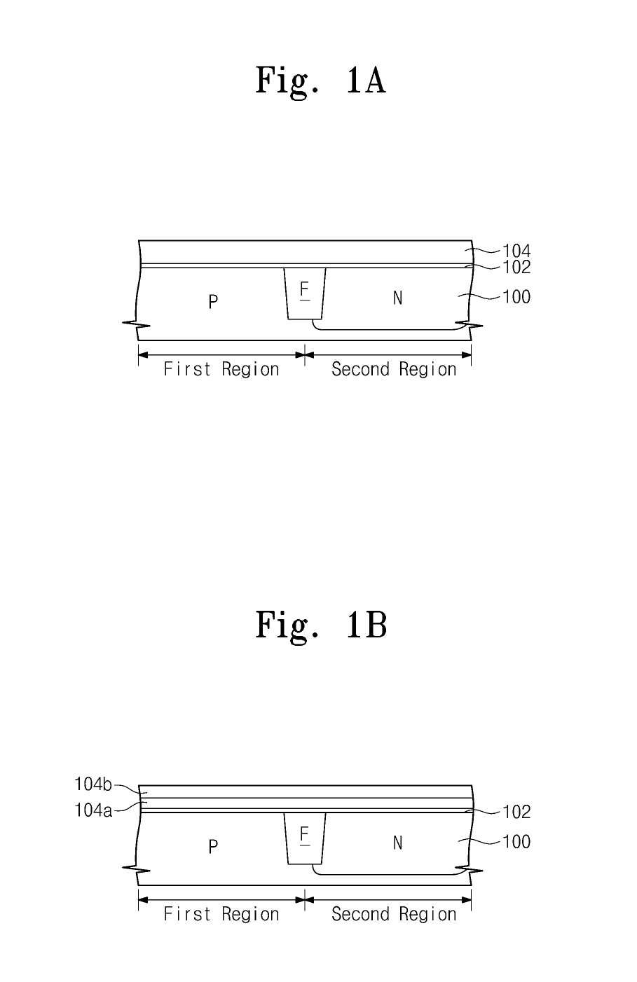

FIGS. 1A, 1B, 2 through 9 are sectional views illustrating a method of fabricating a semiconductor device according to example embodiments.

Referring to FIGS. 1A and 1B, an insulating layer 102 and a polysilicon layer 104 may be sequentially formed on a substrate 100 provided with a device isolation pattern F.

The substrate 100 may include a first region and a second region. In example embodiments, NMOS transistors will be formed in the first region, and PMOS transistors will be formed in the second region.

The substrate 100 may be a semiconductor substrate including silicon, germanium, or silicon/germanium. In addition, the substrate 100 may be n-type or p-type. For example, in the case in which the substrate 100 is p-type, a well region doped with n-type impurities may be formed in the second region. In the opposite case that the substrate 100 is n-type, a well region doped with p-type impurities may be formed in the first region. According to example embodiments, the substrate 100 may be an intrinsic semiconductor substrate, and in this case, a p-well region may be formed in the first region and an n-well region may be formed in the second region.

For the sake of simplicity, the description that follows will refer to an example of example embodiments in which the substrate 100 is p-type and the second region includes a well region doped with n-type impurities. But, example embodiments are not limited thereto.

The device isolation pattern F of the substrate 100 may delimit by an active region. In example embodiments, the active region may include a first active region in the first region and a second active region in the second region.

The insulating layer 102 may be formed on the substrate 100. The insulating layer 102 may include at least one layer of oxide, nitride or oxynitride. The insulating layer 102 may be formed using a thermal oxidation or a chemical vapor deposition.

The polysilicon layer 104 may be formed on the insulating layer 102. In example embodiments, the polysilicon layer 104 may be intrinsic or be doped with at least one of n-type elements, p-type elements, carbon, oxygen, or nitrogen.

According to other example embodiments shown in FIG. 1B, the polysilicon layer 104 may be formed to have a multi-layered structure. For example, the polysilicon layer 104 may include a lower polysilicon layer 104a and an upper polysilicon layer 104b. At least one of the lower and upper polysilicon layers 104a and 104b may be intrinsic or be doped with at least one of n-type elements, p-type elements, carbon, oxygen, or nitrogen.

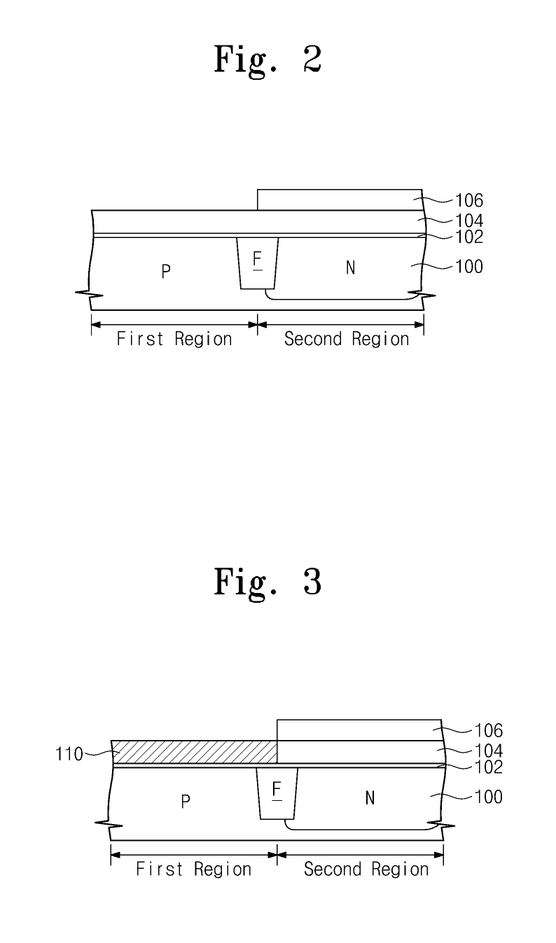

Referring to FIG. 2, a first mask 106 may be formed on the second region to cover partially the polysilicon layer 104 and expose a portion of the polysilicon layer 104 disposed on the first region. In example embodiments, the first mask 106 may include a photoresist pattern.

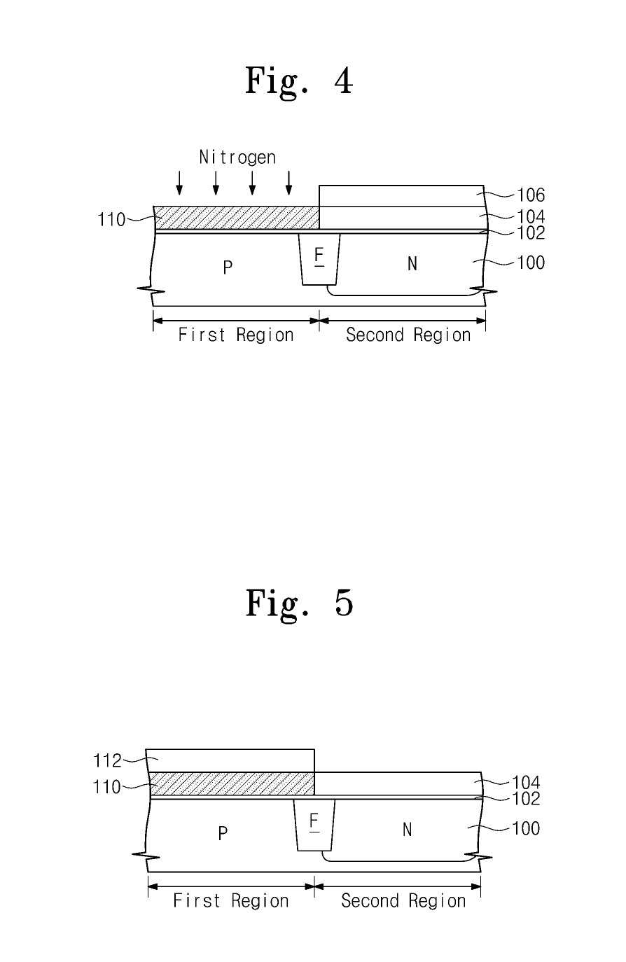

Referring to FIG. 3, n-type impurities may be injected into the portion of the polysilicon layer 104 disposed on the first region to form an N-region 110 in the polysilicon layer 104.

The formation of the N-region 110 may include an ion implantation or a plasma doping process, which may be performed to inject the n-type impurities into the polysilicon layer 104 on the first region. In example embodiments, phosphorous (P) or arsenic (As) may be used as the n-type impurities for the N-region 110.

Referring to FIG. 4, nitrogen may be injected into the N-region 110 of the polysilicon layer 104.

In example embodiments, the injection of nitrogen may be performed using an ion implantation process, a plasma doping process or a thermal nitridation process. The injection of nitrogen into the N-region 110 may be performed at a dose of (e.g., about 10¹⁵ to about 10¹⁶ atom/cm²).

The presence of nitrogen injected into the N-region 110 may prevent the n-type impurities in the N-region 110 from escaping outward. For example, an out-diffusion of n-type impurities (e.g., phosphorous (P)) can be suppressed by a poly grain boundary pinning effect of nitrogen, and this enables a reduction in the loss of n-type impurities.

Referring to FIG. 5, after the injection of nitrogen into the N-region 110 of the polysilicon layer 104, the first mask 106 may be removed from a top surface of the polysilicon layer 104.

Thereafter, a second mask 112 may be formed to selectively cover the N-region 110 of the polysilicon layer 104. The second mask 112 may be formed to expose other portions of the polysilicon layer 104 disposed on the second region. The second mask 112 may include a photoresist pattern.

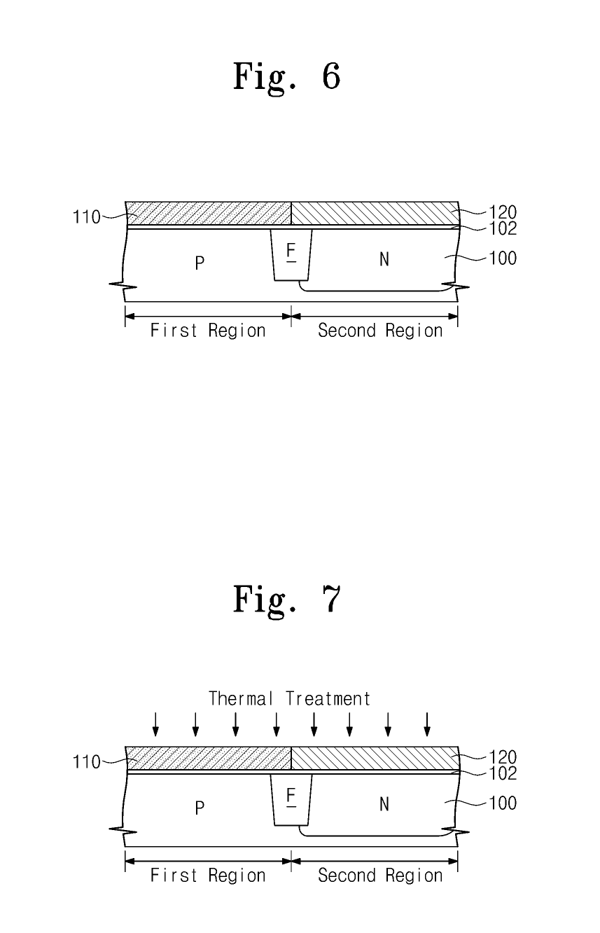

Referring to FIG. 6, p-type impurities may be injected into a portion of the polysilicon layer 104 disposed on the second region to form a P-region 120 in the polysilicon layer 104.

The formation of the P-region 120 may include an ion implantation or a plasma doping process, which may be performed to inject the p-type impurities into the polysilicon layer 104 on the second region. In example embodiments, boron (B) or gallium (Ga) may be used as the p-type impurities for the P-region 120.

After the formation of the P-region 120, the second mask 112 may be removed.

Referring to FIG. 7, a thermal treatment process may be performed on the polysilicon layer 104 provided with the N-region 110 and the P-region 120.

The n-type or p-type impurities in the polysilicon layer 104 may be activated during thermal treatment process. During the activation of impurities, nitrogen doped in the N-region 110 may suppress the n-type impurities (e.g., phosphorous (P)) from being outward diffused, thereby reducing a loss of impurities from the N-region 110.

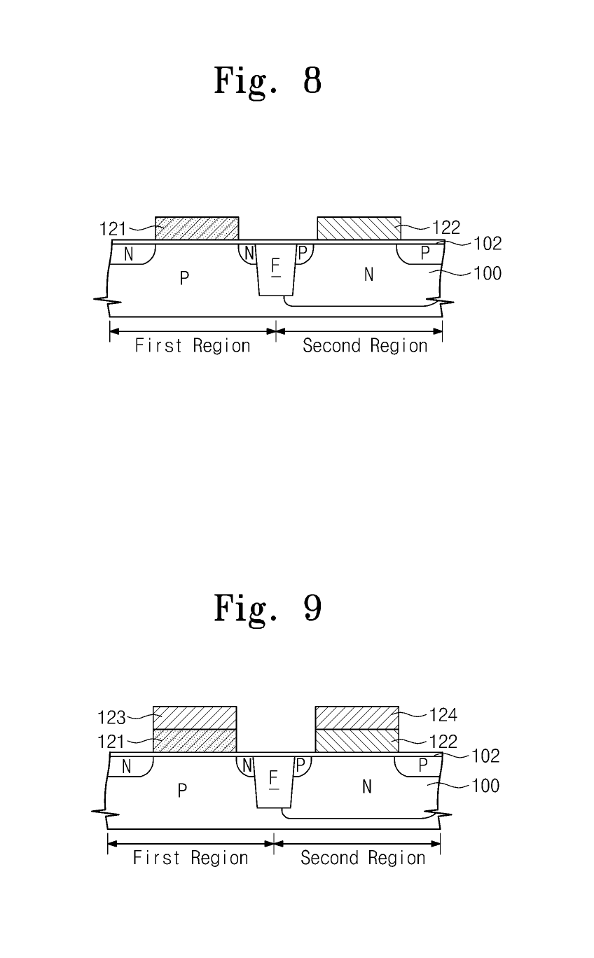

Referring to FIG. 8, the N- and P-regions 110 and 120 of the polysilicon layer 104 may be patterned to form a first gate electrode 121 and a second gate electrode 122, respectively. Next, n-type impurities may be injected into the substrate 100 at both sides of the first gate electrode 121 to form N-source/drain regions, and p-type impurities may be injected into the substrate 100 at both sides of the second gate electrode 122 to form P-source/drain regions.

As a result, the semiconductor device may have a CMOS structure including NMOS transistors disposed on the first region and PMOS transistors disposed on the second region.

Furthermore, according to example embodiments, it is possible to improve electric characteristics of transistors in the semiconductor device, such as capacitance-voltage (C-V) characteristics (e.g., of inversion capacitance) or operating current characteristics (e.g., on-current/off electric current, Iₒₙ-I_{off}).

In addition, it is possible to reduce a loss of n-type impurities from the NMOS electrode and decrease a sheet resistance of the first gate electrode 121, as will be described with reference to the experiment data.

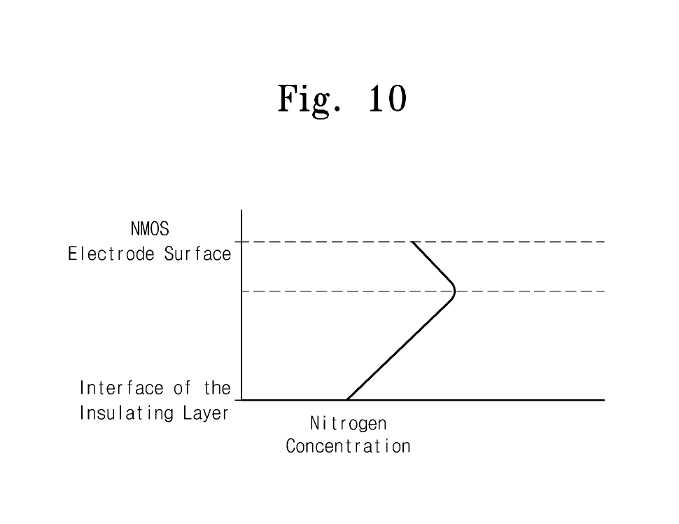

According to other example embodiments depicted in FIG. 9, a metal layer (not shown) may be formed on the polysilicon layer 104 including the N-region 110 and P-region 120.

The metal layer and the polysilicon layer 104 may be etched to form a first gate electrode including an n-type polysilicon pattern 121 and a metal pattern 123 and a second gate electrode including a p-type polysilicon pattern 122 and a metal pattern 124. Thereafter, N-source/drain regions and P-source/drain regions may be formed in the substrate 100. As a result, the semiconductor device may have a CMOS structure including NMOS transistors disposed on the first region and PMOS transistors disposed on the second region.

FIG. 10 is a graph showing a distribution of a nitrogen concentration in NMOS electrode, after performing processes described with reference to FIGS. 4 through 7.

In the experiment, as previously described with reference to FIGS. 3 through 7, a thermal treatment process was performed to a polysilicon layer containing n-type impurities (e.g., phosphorous (P)) and nitrogen that were sequentially injected. As depicted in FIG. 10, a concentration of nitrogen increased gradually as a depth from a surface of the NMOS electrode increased to peak near an upper portion of the NMOS electrode, and thereafter gradually decreased to an interface between the NMOS electrode and an insulating layer.

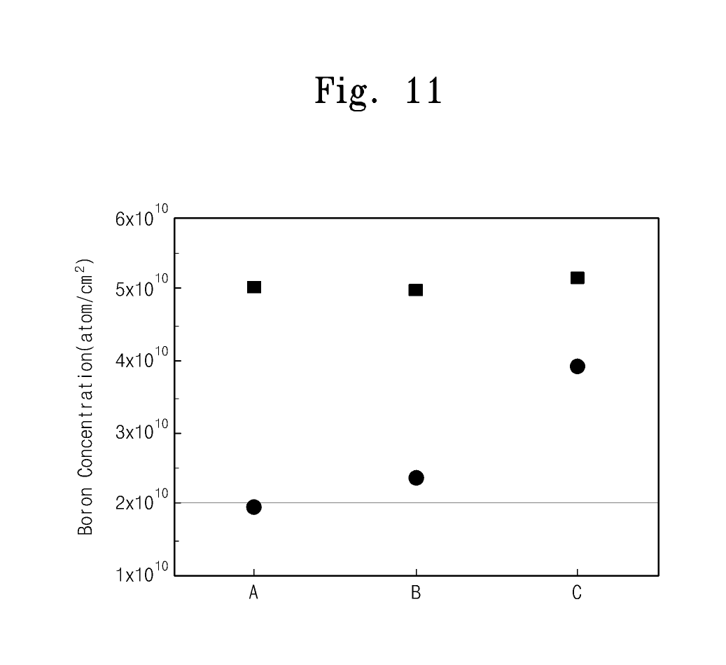

FIG. 11 is a graph showing a relation between a concentration of n-type impurities in an NMOS transistor and a nitrogen doping concentration.

In FIG. 11, the data denoted by a letter A (in x-axis) was measured from NMOS transistors to which the nitrogen injection step of FIG. 4 was not performed, while the data of B and C was measured from NMOS transistors to which the nitrogen injection step of FIG. 4 was performed. The nitrogen doses for samples of B and C were about 1×10¹⁵ atom/cm² and about 5×10¹⁵ atom/cm², respectively. The y-axis of FIG. 11 represents a concentration (atoms/cm²) of n-type impurities in an NMOS transistor.

In FIG. 11, rectangular marks (▪) represent n-type impurity concentrations obtained before performing the thermal treatment process described with reference to FIG. 7, while circular marks () represent n-type impurity concentrations obtained after performing the thermal treatment process.

As shown in FIG. 11, before the thermal treatment process, there was no difference in terms of n-type impurity concentration among the samples (about 5×10¹⁵ atom/cm²). But, after the thermal treatment process, the sample of A had a phosphorous concentration of about 2×10¹⁵ atom/cm² (that is, there was a drop of about 61% in phosphorous concentration), the sample of B had a phosphorous concentration of about 2.3×10¹⁵ atom/cm² (that is, there was a drop of about 53%), and the sample of C had a phosphorous concentration of about 4×10¹⁵ atom/cm² (that is, there was a drop of about 24%).

These experimental results demonstrate that the higher the nitrogen concentration in the NMOS gate electrode, the less a loss of phosphorous from the electrode.

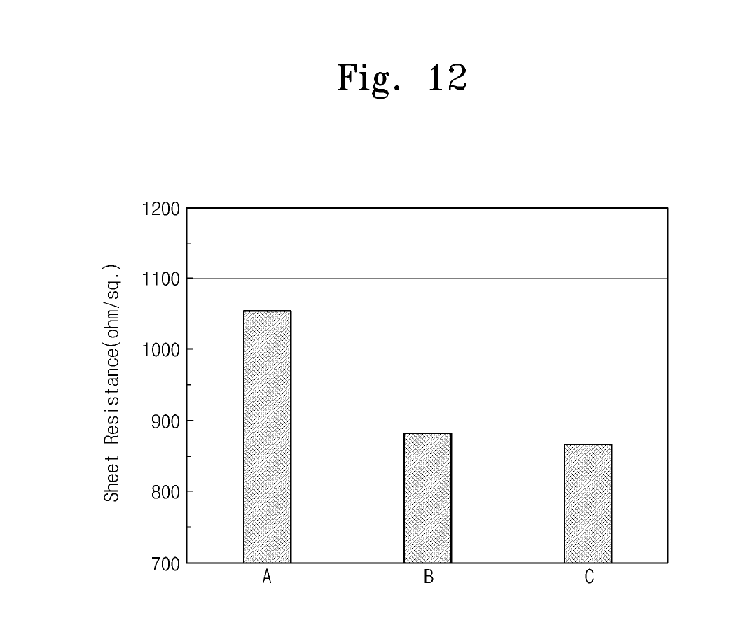

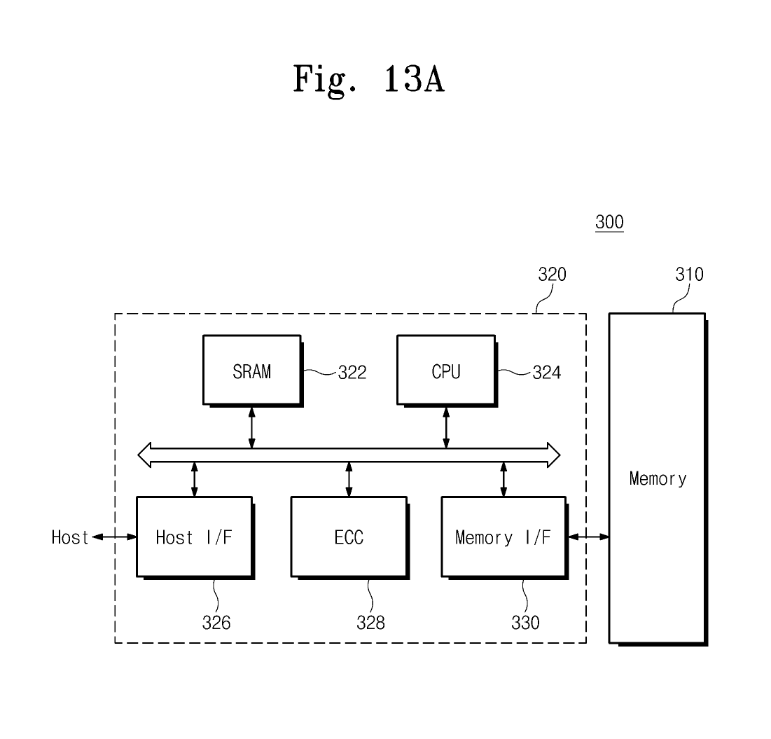

FIG. 12 is a graph showing sheet resistances measured from three transistors A, B and C of FIG. 11.

In FIG. 12, the data denoted by a letter A (in x-axis) was measured from NMOS transistors to which the nitrogen injection step of FIG. 4 was not performed, while the data of B and C was measured from NMOS transistors to which the nitrogen injection step of FIG. 4 was performed. The nitrogen doses for samples of B and C were about 1×10¹⁵ atom/cm² and about 5×10¹⁵ atom/cm², respectively. The y-axis of FIG. 12 represents a sheet resistance (ohm/sq.) of an electrode of a transistor.

As shown in FIG. 12, the sample of A had a sheet resistance of about 1050 ohm/square, the sample of B had a sheet resistance of about 870 ohm/square, and the sample of C had a sheet resistance of about 860 ohm/square.

These experimental results show that the higher the nitrogen concentration in the NMOS gate electrode, the less a sheet resistance of the electrode. That is, the results show that the injection of nitrogen can contribute to reduce the sheet resistance of a NMOS gate electrode.

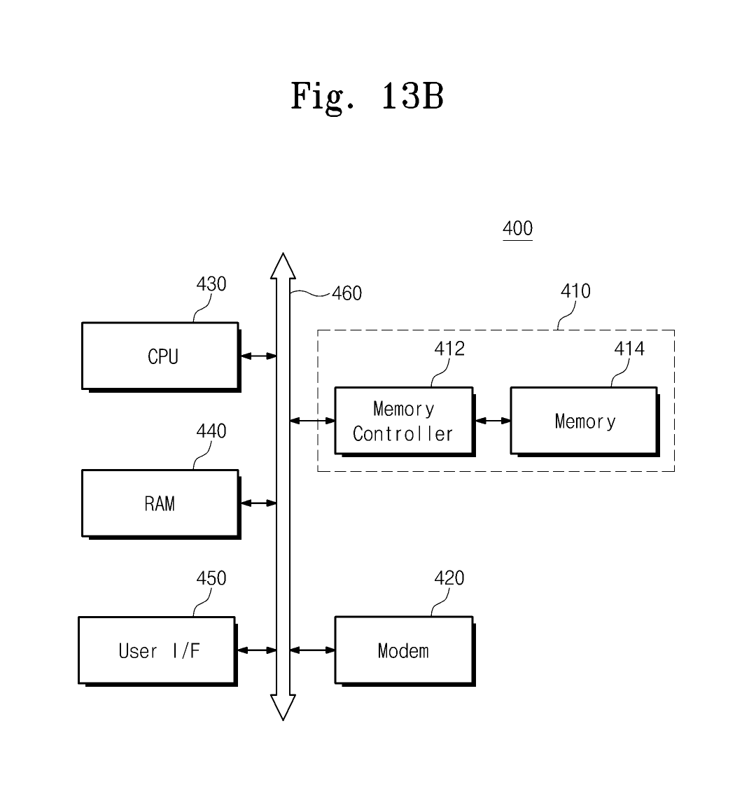

FIG. 13A is a block diagram illustrating a memory card including a semiconductor device according to example embodiments.

Referring to FIG. 13A, a semiconductor device according to example embodiments may be applied to form a memory card 300. The memory card 300 may include a memory controller 320 to control a data exchange between a host and a memory device 310. A static random access memory 322 may be used as an operation memory of a central processing unit 324. A host interface 326 may include at least one data exchange protocol of the host connected to the memory card 300. An error correction code 328 may detect and correct at least one error that may be included in data read from the memory device 310. A memory interface 330 can interface with the memory device 310. The central processing unit 324 can control data exchange of the memory controller 320 with, for example, the memory device 310.

The memory device 310 in the memory card 300 may be the semiconductor device according to example embodiments. Accordingly, it is possible to reduce a loss of n-type impurities, and this enables a reduction in a sheet resistance of NMOS electrode and to improve electric characteristics of the memory device 310 and the memory card 300.

FIG. 13B is a block diagram illustrating an information processing system including a semiconductor device according to example embodiments.

Referring to FIG. 13B, an information processing system 400 may include a semiconductor device according to example embodiments. The information processing system 400 may include a mobile device or a computer. As an illustration, the information processing system 400 may include the memory system 410, a modem 420, a central processing unit (CPU) 430, a random access memory (RAM) 440, and a user interface 450 that are electrically connected to a system bus 460. The memory system 410 may store data processed by the central processing unit (CPU) 430 and data inputted from the outside (e.g., via the user interface 450 and/or the modem 420). The memory system 410 may include a memory 412 and a memory controller 414. The memory system 410 may be the same as the memory card 300 described with reference to FIG. 13A. The information processing system 400 may be provided as a memory card, a solid state disk, a camera image sensor and an application chip set. For example, the memory system 410 may be a solid state disk (SSD). The information processing system 400 may stably and reliably store data in the memory system 410.

According to example embodiments, nitrogen may be injected into a gate electrode layer of NMOS transistor. This enables a reduction in the loss of n-type impurities and a sheet resistance of the gate electrode layer. Thus, it is possible to realize the NMOS transistors with improved electric characteristics.

While example embodiments have been particularly shown and described, it will be understood by one of ordinary skill in the art that variations in form and detail may be made therein without departing from the spirit and scope of the attached claims.

1. A method of fabricating a semiconductor device, comprising:
sequentially forming an insulating layer and a polysilicon layer on a substrate having a first region and a second region;
forming a first mask to cover the polysilicon layer on the second region;
injecting at least one n-type impurity into the polysilicon layer on the first region to form an N-region;
injecting nitrogen into the N-region;
forming a second mask to cover the N-region; and
injecting at least one p-type impurity into the polysilicon layer on the second region to form a P-region.

2. The method of claim 1, wherein the sequentially forming of the insulating layer and the polysilicon layer includes forming an undoped polysilicon.

3. The method of claim 1, wherein the sequentially forming of the insulating layer and the polysilicon layer includes forming a polysilicon doped with at least one selected from n-type elements, p-type elements, carbon, oxygen, and nitrogen.

4. The method of claim 1, wherein the sequentially forming of the insulating layer and the polysilicon layer includes,
forming a lower polysilicon layer on the insulating layer, and
forming an upper polysilicon layer on the lower polysilicon layer,
wherein each of the lower and upper polysilicon layers is a doped or undoped polysilicon layer.

5. The method of claim 1, wherein the injecting of the nitrogen into the N-region is performed using at least one selected from an ion implantation, a plasma doping process, and a thermal nitridation.

6. The method of claim 1, wherein the injecting of the nitrogen into the N-region includes injecting the nitrogen at a dose of about 1×1015 to 1×1016 atom/cm2.

7. The method of claim 1, further comprising:
performing a thermal treatment on the polysilicon layer including the N- and P-regions.

8. The method of claim 1, further comprising:
forming a metal layer on the polysilicon layer including the N- and P-regions; and
etching the metal layer and the polysilicon layer to form NMOS and PMOS electrodes on the first and second regions, respectively.

9. A method of fabricating a semiconductor device, comprising:
providing a polysilicon layer over a substrate having at least two active regions;
providing a first mask over a first active region of the at least two active regions and exposing a second active region of the at least two active regions;
forming a first polysilicon region from the exposed second active region, wherein the first polysilicon region has a conductivity type the same as a conductivity type of the first active region;
introducing nitrogen into the first polysilicon region;
providing a second mask over the first polysilicon region with the nitrogen, wherein the first active region is exposed by the second mask; and
forming a second polysilicon region from the exposed first active region, wherein the second polysilicon region has a conductivity type the same as a conductivity type of the second active region.

10. The method of claim 9, wherein,
the providing of the polysilicon layer includes forming an upper polysilicon layer over a lower polysilicon layer, and
one selected from the upper polysilicon layer and the lower polysilicon layer is doped.

11. The method of claim 9, wherein the introducing of the nitrogen is performed until nitrogen within the first polysilicon region forms a poly grain boundary.

12.-16. (canceled)
